(19) United States
(12) Patent Application Publication
(10) Pub. No.: US 2007/0161231 A1
(43) Pub. Date: Jul. 12, 2007

(54) Method for forming metal wiring in a semiconductor device

(75) Inventor: In Kyu Chun, Gyeonggi-do (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,093

(22) Filed: Dec. 26, 2006

(30) Foreign Application Priority Data
Dec. 29, 2005 (KR) 10-2005-0134400

(51) Int. Cl. H01L 21/4763; H01L 21/44

(52) U.S. Cl. 438/637; 438/653; 438/631; 438/643; 438/645

(57) ABSTRACT

Provided is a method for forming a metal wiring through a damascene process in a semiconductor device. The method includes: forming a metal diffusion barrier on a semiconductor substrate having a via hole and a trench therein; depositing a metal on the metal diffusion barrier, and filling the via hole and trench with the metal; performing a CMP process until an insulating layer is exposed, thereby forming the metal wiring from the metal; etching the exposed insulating layer by predetermined amount; and forming a passivation layer on the entire surface of the semiconductor substrate.

### BACKGROUND OF THE INVENTION

1. Field of the Invention

The present invention relates to a metal wiring of a semiconductor device, and more particularly to a method for forming a metal wiring in a semiconductor device, which can improve the device reliability by removing residue between adjacent metal wirings.

2. Description of the Related Art

Generally, aluminum or aluminum alloy is mainly used as a metal material in a semiconductor manufacturing process. The reason for this is that aluminum or aluminum alloy has good electrical conductivity, excellent adhesion with an oxide layer, and good formability. However, the aluminum or aluminum alloy has a problem of electrical material movement (electromigration), hillock formation, spikes, etc. On account of this, research into metal materials that can be substituted for aluminum has been actively conducted.

Recently, copper Cu, gold Au, silver Ag, cobalt Co, chromium Cr, nickel Ni, etc., have been highlighted as materials that can be substituted for aluminum wiring materials. From among such wiring materials, copper or copper alloy has been widely used, which has small specific resistance and good electromigration property.

However, copper, etc., is not easily dry etched. On account of this, a damascene process is performed to form copper wiring.

Hereinafter, a conventional method for forming a metal wiring in a semiconductor device will be described with reference to the accompanying drawings. FIGS. 1a to 1e are sectional views according to steps illustrating the conventional method for forming a metal wiring in a semiconductor device.

As illustrated in FIG. 1a, a first thin copper layer is formed on a semiconductor substrate 11, and is selectively removed through photolithographic and etching processes, thereby forming a first copper wiring 12. Then, a nitride layer 13 is formed on the entire surface of the semiconductor substrate 11 including the first copper wiring 12, and an insulating interlayer 14 is formed on the nitride layer 13. The nitride layer 13 is used as an etch barrier, and the insulating interlayer 14 is made from a low K material.

Then, a first photoresist 15 is coated on the insulating interlayer 14, and is patterned through exposure and development processes, thereby defining a contact region. Next, the insulating interlayer 14 is selectively removed using the first patterned photoresist 15 and the nitride layer 13 as a mask and an etching end point, respectively, so that a via hole 16 is formed.

As illustrated in FIG. 1b, the first photoresist 15 is removed, and a second photoresist 17 is coated on the entire surface of the semiconductor substrate 11 including the via hole 16, and then is patterned through exposure and development processes. Then, the second patterned photoresist 17 is used as a mask, and a predetermined thickness of the insulating interlayer 14 is selectively removed from the surface thereof by etching, so that a trench 18 is formed. The formation of the via hole and trench in such a process is sometimes known in the art as a “dual damascene” process.

As illustrated in FIG. 1c, the second photoresist 17 is removed, and the nitride layer 13 remaining (exposed) in the lower portion of the via hole 16 is etched. Then, a metal diffusion barrier 19 made from a conductive material such as Titanium Ti or Titanium nitride TiN is formed on the entire surface of the semiconductor substrate 11 including the trench 18 and the via hole 16. Next, a copper seed layer is formed on the metal diffusion barrier 19, and a second copper layer 20a is formed through an electroplating method.

As illustrated in FIG. 1d, a CMP process is carried out on the entire surface of the second copper layer 20a by employing the upper layer of the insulating interlayer 14 as polishing stop. That is, the second copper layer 20a and the metal diffusion barrier 19 are selectively polished, so that a second copper wiring 20 is formed inside the trench 18 and the via hole 16.

As illustrated in FIG. 1e, after the CMP process, silicon nitride (SiN) capping and dielectric materials are deposited on the insulating interlayer 14, so that a passivation layer 22 is formed.

However, the conventional method for forming the metal wiring in the semiconductor device has the following problems.

That is, when the passivation layer 22 is formed by depositing silicon nitride SiN capping and dielectric materials after the CMP process, a micro-bridge may occur between the second copper wiring 20 and another copper wiring (not shown) adjacent to the second copper wiring 20 due to copper (CMP residue) remaining between the two adjacent copper wirings.

### SUMMARY OF THE INVENTION

Accordingly, the present invention is directed to a method for forming a metal wiring in a semiconductor device that substantially obviates one or more such problems due to limitations and disadvantages of the related art.

Accordingly, the present invention has been made to solve the above-mentioned problems, and an object of the present invention is to provide a method for forming a metal wiring in a semiconductor device, which can improve the device reliability by removing residue between metal wirings.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

In accordance with one embodiment of the present invention, there is provided a method for forming a metal wiring in a semiconductor device, the method including: a first step of forming a metal diffusion barrier on an entire surface of a semiconductor substrate (and particularly an insulating layer on the semiconductor substrate) having a via hole and a trench therein; a second step of depositing a metal on the entire surface of the metal diffusion barrier, and filling the via hole and trench with the metal; a third step of performing a CMP process until the insulating layer is exposed, thereby forming the metal wiring from the metal; a fourth step of etching the exposed insulating layer by a predetermined amount; and a fifth step of forming a passivation layer on the entire surface of the semiconductor substrate.

In the method, the etching may comprise dry etching, and the passivation layer may comprise silicon nitride.

In the method, the insulating layer may be etched to a depth of 30 to 50 nm. In one embodiment, the metal comprises copper.

In accordance with another embodiment of the present invention, there is provided a method for forming a metal wiring in a semiconductor device, in which the method may include: forming a first metal wiring on a semiconductor substrate; forming an insulating layer on the semiconductor substrate including the first metal wiring; forming a via hole and a trench overlapping the via hole by selectively removing portions of the insulating layer; forming a metal diffusion barrier on the insulating layer and in the via hole and the trench; forming a metal layer on the metal diffusion barrier; forming a second metal wiring in the via hole and trench by selectively polishing the second metal layer and the metal diffusion barrier (e.g., using a CMP process); etching the insulating layer; and forming a passivation layer on the etched insulating layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIGS. 1a to 1e are sectional views according to steps illustrating a conventional method for forming a metal wiring in a semiconductor device;

FIG. 2 is a sectional view illustrating a metal wiring in a semiconductor device according to the present invention; and

FIGS. 3a to 3g are sectional views according to steps illustrating a method for forming a metal wiring in a semiconductor device according to the present invention.

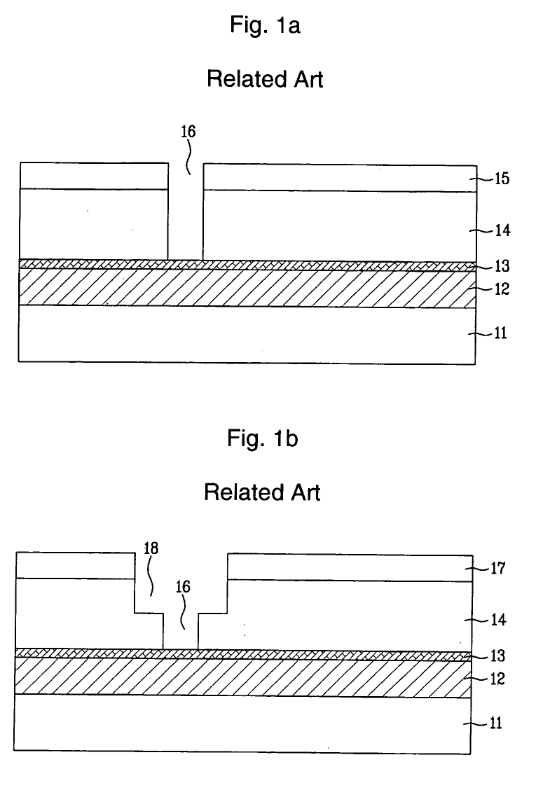

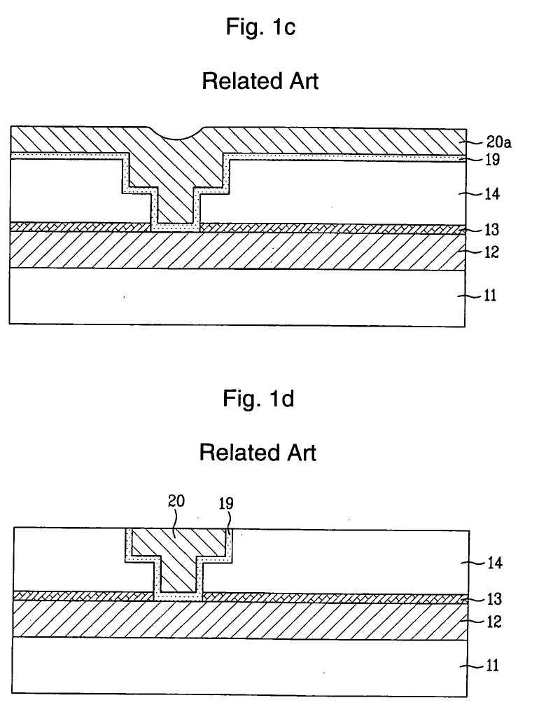

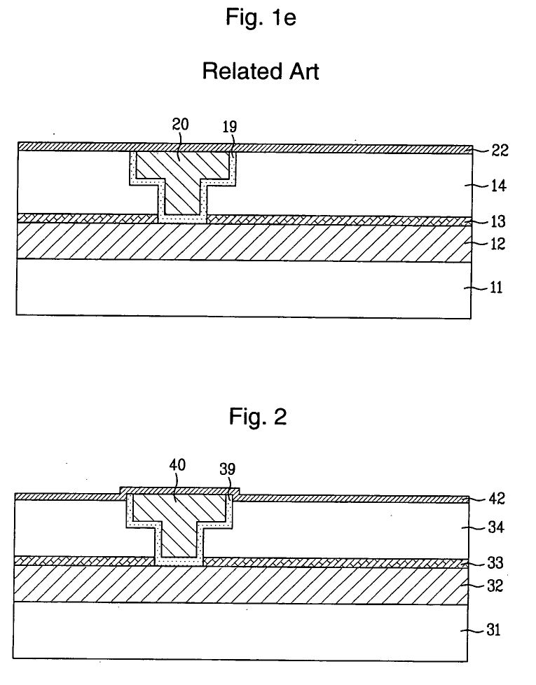

### DETAILED DESCRIPTION OF THE INVENTION

Hereinafter, a metal wiring in a semiconductor device and a forming method thereof according to the present invention will be described in more detail with reference to the accompanying drawings.

FIG. 2 is a sectional view illustrating a metal wiring in a semiconductor device according to the present invention.

As shown in FIG. 2, the semiconductor device includes a first copper wiring 32 formed on a semiconductor substrate 31, a nitride layer 33 formed on the entire surface of the semiconductor substrate 31 including the first copper wiring 32, an insulating interlayer 34 formed on the nitride layer 33, a metal diffusion barrier 39 formed on a via hole and a trench adjacent to the via hole, a second copper wiring 40 filling the via hole and the trench through a CMP process, and a passivation layer 42 formed on the insulating interlayer 34 etched by about 30 to 50 mm through an etching process, wherein the via hole and the trench are formed by selectively removing portions of the insulating interlayer 34 as described herein.

The second copper wiring 40 may be formed by an electroplating method or an electroless plating method after a copper seed layer is formed on the metal diffusion barrier 39.

The second copper wiring 40 is formed inside the via hole and trench by polishing the second copper layer 40 and the metal diffusion barrier 39 (e.g., using a CMP process).

The passivation layer 42 is formed on the insulating interlayer 34, which may have been etched to a depth of about 30 to 50 nm through an etching process after the CMP process. Therefore, the upper portion of the sidewall of the second copper wiring 40 may exposed by about 30 to 50 nm.

Herein, the passivation layer 42 is formed on the insulating interlayer 34 by depositing silicon nitride (e.g., SiN capping and dielectric materials). The passivation layer 42 is formed on the sidewall of the second copper wiring 40, so that adhesion between the metal diffusion barrier 39 and the insulating interlayer 34 is improved, which results in the improvement of device reliability.

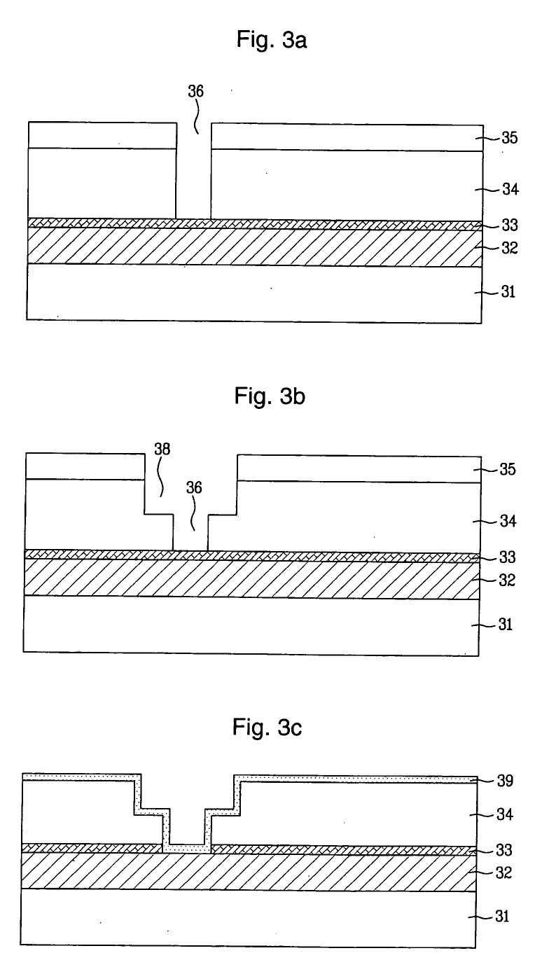

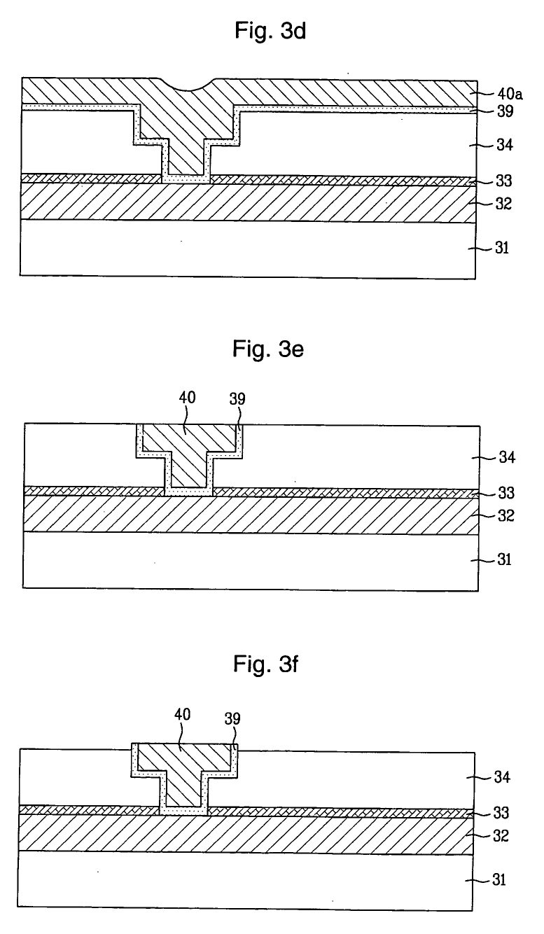

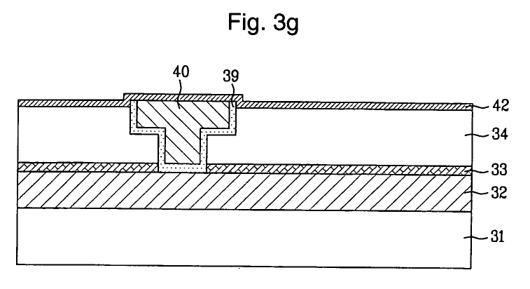

FIGS. 3a to 3e are sectional views according to steps illustrating a method for forming a metal wiring in a semiconductor device according to the present invention.

As illustrated in FIG. 3a, a first copper layer is formed on the semiconductor substrate 31 (or on/in a dielectric layer thereon) by the dual damascene process described herein, thereby forming the first copper wiring 32. Alternatively, metal layer 32 may comprise aluminum or an aluminum alloy, which is selectively removed through photo and etching processes, thereby forming a first metal wiring 32.

Then, the nitride layer 33 is formed on the entire surface of the semiconductor substrate 31 including the first copper wiring 32, and the insulating interlayer 34 is formed on the nitride layer 33. Herein, the nitride layer 33 is used as an etch barrier, and the insulating interlayer 34 comprises a material having a low dielectric constant or an ultra low-k material (k<2.5). In various embodiments, the insulating layer 34 comprises a plurality of stacked insulator layers, such as an undoped silicate glass (silicon oxide, or USG)/fluorosilicate glass (FSG)/USG stack, a silicon-rich oxide/USG/FSG/USG stack, or a USG/silicon oxycarbide (SiOC, which may be hydrogenated [SiOCH])/USG stack.

Then, the first photoresist 35 is coated on the insulating interlayer 34 and patterned through exposure and development processes, thereby defining a contact region. Next, the insulating interlayer 34 is selectively removed using the first patterned photoresist 35 as a mask and the nitride layer 33 as an etching end point, respectively, so that a via hole 36 is formed.

As illustrated in FIG. 3b, the first photoresist 35 is removed, and a second photoresist 37 is coated on the entire surface of the semiconductor substrate 31, including the via hole 36, and then is patterned through exposure and development processes. Then, the second patterned photoresist 37 is used as a mask, and the insulating interlayer 34 is selectively removed by a predetermined thickness (or to a predetermined depth) from the surface thereof, so that a trench 38 is formed.

Next, the second photoresist 37 is removed, and the nitride layer 33 remaining (or exposed) in the lower portion of the via hole 36 is etched. Herein, the nitride layer 33 is etched (by wet or dry etching) using the second photoresist 37 or the insulating interlayer 34 as a mask.

As illustrated in FIG. 3c, a metal diffusion barrier 39 made from a conductive material such as a Tantalum (Ta)/Tantalum nitride (TaN) bilayer is formed on the entire surface of the semiconductor substrate 31, including in the trench 38 and the via hole 36.

As illustrated in FIG. 3d, a copper seed layer is formed on the metal diffusion barrier 39, and a second copper layer 40a is formed thereon using an electroplating or electroless plating method.

As illustrated in FIG. 3e, a CMP process is carried out on the entire surface of the second copper layer 40a, employing the upper layer of the insulating interlayer 34 as a polishing stop. That is, the second copper layer 40a and the metal diffusion barrier 39 are selectively polished, so that a second copper wiring 40 is formed inside the trench 38 and the via hole 36.

As illustrated in FIG. 3f, an etching process is carried out on the insulating interlayer 34. In such a case, it is preferred that an etching depth is about 30 to 50 nm. Therefore, the sidewall of the second copper wiring 40 is exposed by about 30 to 50 nm. After the etching process and CMP process for the insulating interlayer 34, the residue of the copper thin layer 40a which may exist on the insulating interlayer 34 is completely removed. Consequently, there is little or no possibility that microbridges can occur between the second copper wiring 40 and another copper wiring (not shown) adjacent to the second copper wiring 40.

As illustrated in FIG. 3g, a silicon nitride (SiN) layer (passivation layer) is formed on the etched insulating interlayer 34. The silicon nitride layer may also be considered to be a capping layer. Consequently, the passivation layer 42 is formed on the entire surface of the insulating interlayer 34 to cover the exposed sidewall and entire surface of the second copper wiring 40, so that adhesion between the metal diffusion barrier 39 and the insulating interlayer 34 is improved, which results in the improvement of device reliability.

As described above, a metal wiring in a semiconductor device and a forming method thereof according to the present invention can achieve the following effect.

In the present invention, after a CMP process, an insulating interlayer existing between adjacent copper wirings is etched by a predetermined amount, and a silicon nitride capping (and/or dielectric material) layer(s) are deposited on the insulating interlayer to form a passivation layer. Consequently, there is little or no possibility of microbridges occurring, in which adjacent copper wirings are interconnected due to copper (residue) remaining from the CMP process.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for forming a metal wiring in a semiconductor device, comprising:
forming a metal diffusion barrier on an entire surface of a semiconductor substrate having an insulating layer with a via hole and a trench therein;
depositing a metal on the entire surface of the metal diffusion barrier has been formed, and filling the via hole and trench with the metal;
performing a CMP process until the insulating layer is exposed, thereby forming the metal wiring from the metal;
etching the exposed insulating interlayer by predetermined amount; and
forming a passivation layer on the semiconductor substrate.

2. The method according to claim 1, wherein the etching comprises dry etching.

3. The method according to claim 1, wherein the passivation layer comprises silicon nitride.

4. The method according to claim 1, wherein the insulating layer is etched to a depth of 30 to 50 nm.

5. The method according to claim 1, wherein the metal comprises copper.

6. The method according to claim 1, wherein the passivation layer is deposited on an entire surface of the semiconductor substrate.

7. The method according to claim 1, wherein the insulating layer has a plurality of via holes and a plurality of trenches therein.

8. The method according to claim 7, wherein each of the plurality of trenches overlaps with the plurality of via holes.

9. A method for forming metal wiring in a semiconductor device, the method comprising:
forming a via hole and a trench overlapping the via hole by selectively removing portions of an insulating layer on a semiconductor substrate;
forming a metal diffusion barrier on the insulating layer including in the via hole and the trench;
forming a metal layer on the metal diffusion barrier;
forming the metal wiring in the via hole and trench by polishing the metal wiring and the metal diffusion barrier;
etching the insulating layer by a predetermined amount; and
forming a passivation layer on the etched insulating layer.

10. The method according to claim 9, wherein etching the insulating layer comprises dry etching.

11. The method according to claim 9, wherein the passivation layer comprises silicon nitride.

12. The method according to claim 9, wherein the insulating layer is etched to a depth of 30 to 50 nm.

13. The method according to claim 9, wherein the metal layer comprises copper.

14. The method according to claim 9, further comprising forming an underlying metallization on the semiconductor substrate.

15. The method according to claim 14, further comprising forming the insulating layer on the semiconductor substrate, including the first metal wiring.

16. The method according to claim 9, wherein polishing the second metal wiring and the metal diffusion barrier comprises a CMP process.
